(19) United States
(12) Patent Application Publication
(10) Pub. No.: US 2020/0035484 A1
(43) Pub. Date: Jan. 30, 2020

(54) SYSTEM AND METHOD FOR CHEMICAL AND HEATED WETTING OF SUBSTRATES PRIOR TO METAL PLATING

(71) Applicant: Lam Research Corporation, Fremont, CA (US)

(72) Inventors: Justin OBERST, Beaverton, OR (US); Bryan BUCKALEW, Tualatin, OR (US); Stephen J. BANIK, Portland, OR (US); Meng Wee Edwin GOH, Wilsonville, OR (US); Joseph RICHARDSON, Sherwood, OR (US); Lawrence OSSOWSKI, Tigard, OR (US); Marc QUAGLIO, Sherwood, OR (US); Douglas HIGLEY, Portland, OR (US)

(21) Appl. No.: 16/048,776

(22) Filed: Jul. 30, 2018

(51) Int. Cl. H01L 21/02; B08B 3/08; B08B 3/10; B08B 3/14; B08B 3/04; B08B 3/02; B08B 7/04; C25D 5/34; C25D 7/12; H01L 21/288

(52) U.S. Cl. CPC H01L 21/02068; B08B 3/08; B08B 3/10; B08B 3/14; B08B 3/041; B08B 2203/007; B08B 7/04; C25D 5/34; C25D 7/123; H01L 21/2885; B08B 2203/002; B08B 3/02

(57) ABSTRACT

A wetting tool that provides improved wettability and debris removal from features defined by a patterned resist layer on a substrate. The substrate wetting tool relies on a wetting solution having a pH of 2.0 or less and/or a temperature ranging from 20 to 50° C. With a pH of 2.0 or less, the resist material used to form features chemically reacts, making it more hydrophilic. The wetting solution is therefore attracted into the features, beneficially reducing the chance of bubble formation and removing debris. At elevated temperatures, the heated wetting solution improves particle de-lamination and aids in dissolving debris and oxides from the substrate surface.

### BACKGROUND

Electroplating is a process that involves the deposition of a thin layer under an applied electric field onto a work piece.

In the semiconductor industry, electroplating is commonly used. For example, electroplating is typically used to form the interconnect between transistors and vias between different levels on a semiconductor wafer.

The various features on a semiconductor wafer that are electroplated are usually defined by a patterned resist layer. For instance, a blanket resist layer is first formed over a copper seed layer. The resist layer is then patterned to form features that expose underlying regions of the copper seed layer to be plated. The wafer substrate then undergoes an electroplating process, resulting in a metal layer being formed on the exposed portions of the seed layer.

The electroplating of small features on semiconductor substrates can be problematic for several reasons. Often air bubbles and/or debris can get trapped inside the small features defined by the patterned resist, interfering or obstructing the plating process. The resulting plated metal layers may be of poor quality, inadequate thickness, non-uniform, or may not form at all in severe situations.

Tools with wetting chambers are commonly used in the semiconductor industry. With such tools, wafer substrates are “wetted” in the chamber with a rinsing solution such as deionized (DI) water or other chemical solution, typically, having a pH level of two or greater. By wetting the wafer substrate, air bubbles can be prevented and debris is attempted to be removed from such features prior to plating.

During a wetting procedure, a wafer substrate is placed in a chamber and a wetting solution is introduced into the chamber via a spray nozzle as the wafer is spinning After a predetermined period of time, either following a single or multiple spin/wetting cycles, the fluid is drained from the chamber. Thereafter, the wafer substrate is transported from the chamber to an electroplating chamber for plating.

Existing wetting tools have some drawbacks. The resist commonly used for defining features is typically hydrophobic. As a result, wetting solutions having a pH of 2.0 or higher are often repelled in the very locations where the wetting solution is needed to remove air pockets and/or debris. Also, the wetting solution introduced into the wetting chamber is typically at ambient or room temperature. At such temperatures, the ability of the solution to clean and remove debris is compromised.

An improved system and method for chemical and heated wetting of semiconductor substrates is therefore needed.

### SUMMARY

A wetting tool that provides improved wettability and debris removal from features defined by a patterned resist layer on a substrate is disclosed.

The substrate wetting tool includes a chamber, a substrate pedestal for supporting a substrate within the chamber and a wetting solution distribution system for introducing a wetting solution into the chamber. The wetting solution has a pH of 2.0 or less and/or a temperature ranging from 20 to 50° C. With a pH of 2.0 or less, the resist material used to form features chemically reacts, making it more hydrophilic. As a result, the wetting solution is attracted into the features, beneficially reducing the chance of bubble formation and aiding in the removal of debris. In addition, at elevated temperatures, the wetting solution changes the surface kinetics, yielding improved particle de-lamination from the substrate. The elevated temperature of the wetting solution can also aid in dissolving any debris or oxides from the substrate surface. As a result, the ability of the wetting solution to clean debris within features is further enhanced.

In various embodiments, the low pH level and/or heated wetting solution can be used in a wide variety of different wetting sequences implemented by the tool. Such wetting sequences may include multiple wetting cycles with a wetting solution having pH of 2.0 or less and/or a temperature ranging from 20 to 50° C., one or more wetting cycles with a wetting solution having pH of 2.0 or less and/or a temperature ranging from 20 to 50° C. and other wetting cycles with a wetting solution without one or both of these attributes (e.g., a pH of more than 2.0 and/or a temperature less than 20° C.), additional wetting cycles with DI water, etc.

In yet other embodiments, the wetting chamber may be implemented in a wide variety of different types of tools. For instance, the tool may be a stand-alone wetting tool with one or multiple wetting chambers. Alternatively, the tool may be some type of hybrid tool that includes one or more wetting chamber(s) along with other capabilities, such as one or more electroplating chamber(s).

### BRIEF DESCRIPTION OF THE DRAWINGS

The present application, and the advantages thereof, may best be understood by reference to the following description taken in conjunction with the accompanying drawings in which:

FIG. 1 is a block diagram of a wetting tool that can be used for wetting substrates in accordance with a non-exclusive embodiment of the invention.

FIGS. 2A-2D are cross-sectional views of the wetting of a feature on a semiconductor substrate in accordance with a non-exclusive embodiment of the invention.

FIG. 3 is a flow diagram illustrating a first chemical and heated wetting process in accordance with a non-exclusive embodiment of the invention.

FIG. 4 is a flow diagram illustrating a second chemical and heated wetting process in accordance with a non-exclusive embodiment of the invention.

In the drawings, like reference numerals are sometimes used to designate like structural elements. It should also be appreciated that the depictions in the figures are diagrammatic and not necessarily to scale.

### DETAILED DESCRIPTION

The present application will now be described in detail with reference to a few non-exclusive embodiments thereof as illustrated in the accompanying drawings. In the following description, numerous specific details are set forth in order to provide a thorough understanding of the present disclosure. It will be apparent, however, to one skilled in the art, that the present discloser may be practiced without some or all of these specific details. In other instances, well known process steps and/or structures have not been described in detail in order to not unnecessarily obscure the present disclosure.

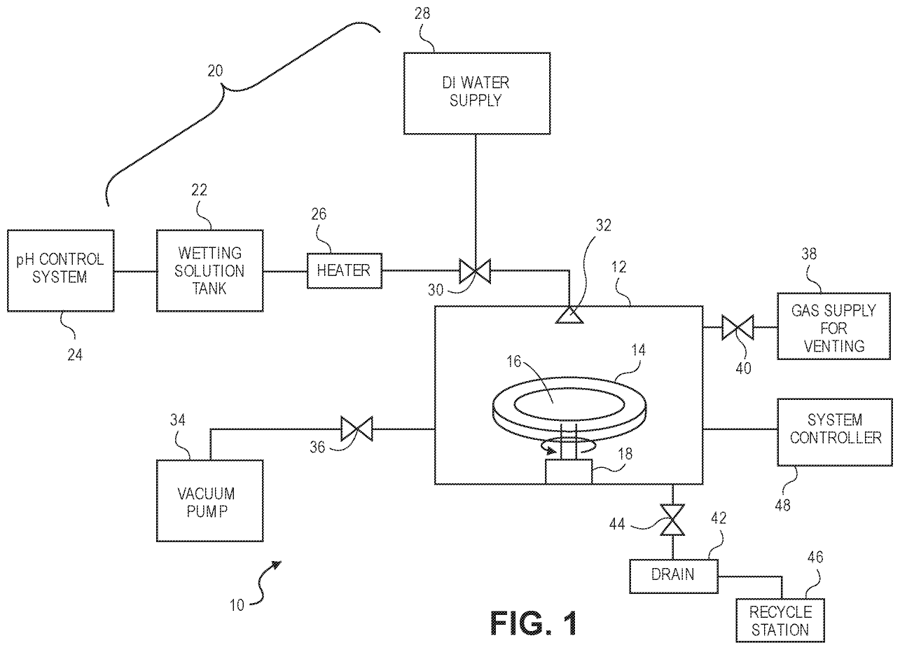

Referring to FIG. 1, a block diagram a wetting tool 10 for the wetting of substrates is illustrated. In a non-exclusive embodiment, the wetting tool 10 may be use for the wetting of semiconductor substrates prior to plating.

The wetting tool 10 includes a chamber 12, a substrate pedestal 14 for supporting a substrate 16, such as a semiconductor wafer, and a mechanism 18 for rotating the substrate pedestal 14 and substrate 16. In one embodiment, the mechanism 18 is capable of rotating the substrate pedestal 14 and substrate 16 in the range of 80 to 200 revolutions per minute (rpm). But in other embodiments, other rmp values or ranges may be used. For example, rmp values of 40, 30, 20 or less can be used at the low end of a range and rmp values of 200, 300, 400 or higher can be used at the high end of the range. It should be noted that although specific RMP values and/or ranges may be provided herein, any suitable rmp value or range may be used. As such, the specific values or ranges provided herein are merely exemplary and should not be construed as limiting.

The wetting tool 10 also includes a wetting solution distribution system 20 which includes one or more wetting solution(s) tank(s) 22 for storing one or more wetting solutions, a pH control system 24 for measuring and adjusting the pH of the one or more wetting solution(s) stored in the tank(s) 22, a heater 26 for selectively heating the wetting solution(s), a deionized (DI) water supply 28, a three way valve 30 and a spray nozzle 32 provided inside the chamber 12.

The wetting solution(s) maintained in tank(s) 22 may include one or more of the following: (a) an inorganic acid, (b) an organic acid, (c) a dissolved gas in water, (d) dissolved carbon dioxide in water, (e) DI water, (f) DI and degassed water, (g) carbonic acid, (h) sulfuric acid, and (i) methane sulfonic acid.

The pH control system 24 is arranged to monitor the pH of the solution(s) maintained in the tank(s). In various embodiments, the pH control system 24 may rely on a pH probe, a conductivity meter, a density meter, or a combination thereof to measure the composition of the wetting solution(s). In various embodiments, the pH of at least one wetting solution is maintained at 2.0 or less. In other embodiments, one wetting solution may have a pH of 2.0 or less, while a second wetting solution has a pH of 2.0 or more. More details are provided below with respect to several non-exclusive wetting process flows. The pH of the wetting solutions can be adjusted by the pH control system 24 as needed by acid dosing if the pH needs to be lowered, base dosing if the pH needs to be raised higher, by adding DI water (which typically has a pH of slightly less than neutral or 7.0) if the pH needs to be raised or lowered, or by gas dosing to either increase or decrease the pH. For example, carbon dioxide gas can be used to reduce the pH of the wetting solution(s).

The heater 26 can be any type of heater capable of heating the one or more wetting solutions maintained in the storage tank(s) 22. In various non-exclusive embodiments, the heater 26 is capable of heating the one or more wetting solution(s) in the temperature range of 20 to 50° C.

The three way valve 30 can be selectively opened and closed to supply the one or more wetting solution(s) maintained in the storage tank(s) 22 and/or DI water from supply 28 to the spray nozzle 32. In an alternative embodiment, the valve 30 can controlled to simultaneously supply both the wetting solution(s) and DI water to spray nozzle 32.

The spray nozzle 32 is depicted as positioned at the top of the chamber 12 for spraying wetting solutions and/or DI water directly down onto the top surface of substrate 16. In other embodiments, the spray nozzle 32 can be positioned on or adjacent a side wall of the chamber 12 and/or multiple spray nozzles 32 (not shown) may be provided at different positions within the chamber 12. Regardless of the number and/or positions of the spray nozzles 32, the purpose is to supply the wetting solution(s) and/or DI water onto the top surface of the substrate 16 while spinning on the pedestal 18. In yet other non-exclusive embodiments, the spray nozzles 32 may supply wetting solution(s) and/or DI water at a rate of 0.6 to 2.4 liters per minute.

The wetting tool 10 also optionally includes a vacuum pump 36 and a valve 36. When the valve 36 is opened and the pump 34 is operational, a vacuum pressure is created inside the chamber 12. In various non-exclusive embodiments, the vacuum pressure may range from 25 to 100 Torr and have a set-point of approximately 70 Torr. It should be understood that these Torr values/ranges are merely exemplary and that others may be used. In yet other embodiments, the wetting tool 10 may not include the vacuum pump 36. In which case, the chamber 12 is maintained at or near atmosphere.

The wetting tool 10 further includes a venting gas supply 38 and a valve 40. When the valve 40 is opened, gas from the supply 38 is vented into the chamber 12. In various embodiments, the gas is nitrogen, argon, and/or atmosphere. In yet other embodiments, the vented pressure within the chamber 12 ranges from 740 to 760.

The wetting tool 10 also includes a drain 42, a drain valve 44 and optionally a recycle station 46. When the valve 44 is opened, wetting solution and/or DI water in the chamber 12 is removed via the drain 42. In optional embodiments, the recycle station 46 may be used to clean and filter the drained wetting solution and/or DI water so it can be reused.

The system controller 48 is employed to control operation of the wetting tool 10 prior to, during, and post wetting of substrates 16. The system controller 48 controls the various elements, such as the pH control system 24, heater 26, vacuum pump 34, and valves 30, 36, 40 and 44 to coordinate the wetting of substrates 16 in accordance with various embodiments, as described in more detail below.

The system controller 48 typically includes one or non-transient computer readable medium devices for storing system control software or code computer and one or more processors for executing the code. The term “non-transient computer readable medium” is used generally to refer to media such as main memory, secondary memory, removable storage, and storage devices, such as hard disks, flash memory, disk drive memory, CD-ROM, and other forms of persistent memory and shall not be construed to cover transitory subject matter, such as carrier waves or signals. The processor may include a CPU or computer, multiple CPUs or computers, analog and/or digital input/output connections, motor controller boards, etc.

In certain embodiments, the system controller 48, running or executing the system control software or code, manages all or at least most of the activities of the tool 10, including such activities as controlling the timing of wetting operations, flow rates, pH levels and/or temperature of the wetting solution(s) and/or DI water, pressure levels inside the process chamber 12, the introduction and removal of substrates 16 into the chamber 12, etc.

The system controller 48 may also include a user interface (not shown). The user interface may include a display screen, graphical software displays of indicative of operating parameters and/or process conditions of the tool 10, and user input devices that allow a human operator to interface with the tool 10, such as pointing devices, keyboards, touch screens, microphones, etc.

Information transferred between the system controller 48 and the various components of the tool 10 may be in the form of signals such as electronic, electromagnetic, optical, or other signals capable of being transmitted and/or received via any communication link that carries signals and may be implemented using wiring or cabling, fiber optics, a phone lines, a cellular phone link, a wireless or radio frequency link, and/or other communication channels.

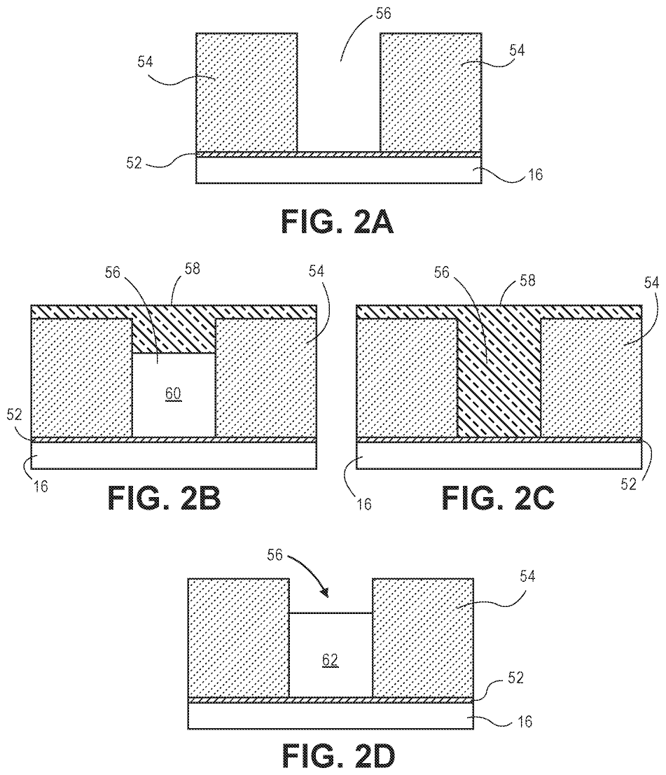

FIGS. 2A-2D are a cross-sectional views a feature on a semiconductor substrate prior, during and after wetting in wetting tool 10.

FIG. 2A shows a cross-section of a substrate 16, a copper seed layer 52 formed over the substrate 16, and a patterned resist layer 54 that defines a feature 56. The feature 56 in FIG. 2A is pre wetting.

FIG. 2B shows the substrate 16 during wetting by a wetting solution 58. In this diagram, however, an air bubble 60 is present. As a result, the wetting solution is unable to reach the seed layer 52 at the bottom of the feature 56. As previously noted, the presence of an air bubble (or other debris) is problematic because it may prevent or obstruct the subsequent electroplating process, resulting in non-uniform or a poor quality layer of metal formed within the feature 56 defined by the patterned resist 54.

FIG. 2C, in contrast, shows the substrate 16 with the wetting solution 58 filling the feature 56 down to the seed layer 52. As a result, the likelihood of the trapping of air bubbles 60 and/or debris collecting in the region above the seed layer 52 defined by the feature 54 is significantly reduced or altogether eliminated.

FIG. 2D shows the formation of a metal layer 62 in the feature 56 post wetting in a subsequent electroplating process step. In this example, the plating process forms a high-quality metal layer of uniform thickness, substantially attributable to the removal of air bubble and debris in the previous wetting step, as depicted in FIG. 2C.

The Applicant has found that by using wetting solution(s) having a pH of 2.0 or less has a number of benefits. Namely, the resist material used to form features 56 can be hydrophobic. This property tends to push away the wetting solution in the very areas it is needed the most, such as inside the features 56. The use of a wetting solution of a pH of 2.0 or less, however, can chemically react with the resist material, making it more hydrophilic. As a result, the wetting solution is not repelled, but attracted, into the feature 56, beneficially reducing the chance of bubble trapping and aiding in the removal of debris.

The Applicant has also found that by elevating the temperature of the wetting solution from ambient or room temperature to 20 to 50° C., additional benefits are realized. At elevated temperatures, the wetting solution changes the surface kinetics yielding particle delamination from the substrate. The elevated temperature can also aid in dissolving any debris or oxides from the substrate surface.

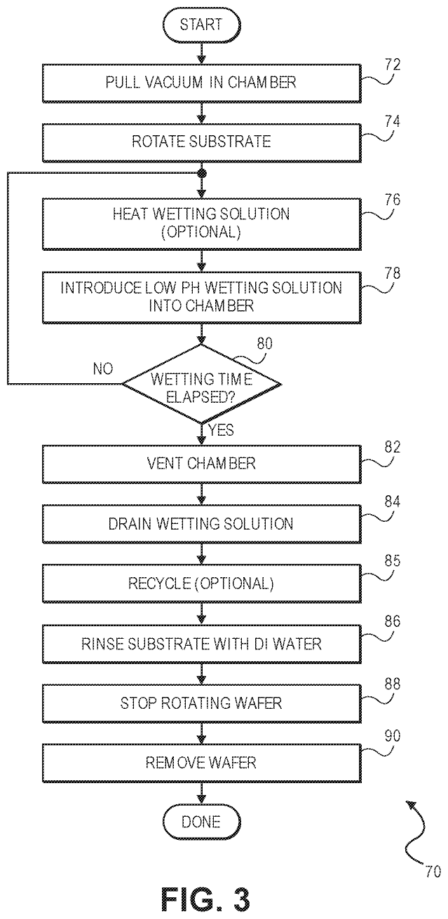

FIG. 3 is a flow diagram 70 illustrating a first chemical and/or heated wetting process performed by tool 10 on a substrate 16 is shown. The steps below are coordinated by the system controller 48. It should be noted that the various parameters and values, such as pressure ranges, rpm rates, temperature ranges, flow rates, etc., provided below are exemplary and are not intended to be construed as limiting. Other parameters and values may be used.

In step 72, the chamber 12 is closed and the valve 36 is opened, allowing the vacuum pump 34 to create a vacuum in the chamber 10. In various embodiments, the vacuum pressure ranges from 25 to 100 Torr.

In step 74, the mechanism 18 rotates the substrate pedestal 14 and substrate 16 at a rate ranging anywhere from 20 or less to 400 or more revolutions per minute (rpm) may be used. In a non-exclusive embodiment, the rate is 80 rpm. In optional step 76, the wetting solution is heated by the heater 26. In various embodiments, the temperature range is 20 to 50° C. In a specific embodiment, the temperature is 40° C.

In step 78, the wetting solution distribution system 20 introduces the wetting solution into the chamber 12 via the spray nozzle(s) 32. In a preferred, but non-exclusive embodiment, the wetting solution is heated within the range of 20 to 50° C. and has a pH level of 2.0 or less. In one alternative embodiment, the wetting solution can be heated within the range of 20 to 50° C., but has a pH level of 2.0 or more. In yet another embodiment, the wetting solution has a pH level of 2.0 or less, but is maintained at ambient or room temperature and is not heated. In yet other embodiments, the wetting fluid is introduced at a rate of 0.6 to 1.8 liters per minute.

In decision 80, the system controller 48 keeps track of the amount of time the substrate has been exposed to the wetting solution. Prior to a predetermined period of time expiring, steps 76 and/or 78 are performed, resulting in the wetting solution sprayed on the substrate 16 while rotating in the chamber. 12. In a non-exclusive embodiment, the predetermined amount of time is 30 seconds. In other embodiments, the predetermined amount of time may range from 10 to 120 seconds. It should be noted that prior to the expiration of the wetting time, the substrate can undergo a single wetting/spin cycle or multiple wetting/spin cycles. In the case of the latter, different or the same wetting solution(s) may be used for each cycle.

In step 82, after the predetermined amount of wetting time has expired, the system controller 48 activates valve 40 to vent the chamber 12 with a gas, such as nitrogen. In various embodiments, the pressure within the chamber 12 ranges from 740 to 760 Torr while vented. In yet other alternative embodiments, the substrate may be spun at a high rate after the wetting time has expired but prior to the venting. By spinning the substrate at the high rate (e.g., at around 400 rpm), excess wetting solution is spun off the substrate.

In step 84, the system controller 48 activates the valve 44, allowing the drain 42 to drain the wetting solution from the chamber 12.

In an optional step 85, the drained wetting solution can be recycled, filtered as needed, and returned to the wetting solution tank(s) 22 for later use.

In step 86, the system controller 48 activates the valve 30, introducing DI water from supply 28 into the chamber 12 via the nozzle(s) 32. In a non-exclusive embodiment, the substrate is exposed to the DI water for approximately 60 seconds. In other embodiments, the exposure to DI water may be of a longer or shorter duration than the 60 seconds. By rinsing with DI water, the wetting solution chemistry is removed from the substrate prior to any subsequent plating step.

In step 88, the mechanism 18 stops rotating the substrate 16.

In step 90, the substrate is removed from the chamber 16.

With the above embodiment, step 86 of rinsing the substrate with DI water substantially removes the wetting solution from the substrate. As a result, continued reaction of the resist to the wetting solution is mitigated or eliminated. Removal of the chemical wetting solution with DI water also minimizes transfer of the solution to the plating module. It should be noted however that the rinsing with DI water is optional. If further chemical reaction of the resist layer and chemical transfer are not issues, the rinse step with DI water need not be performed.

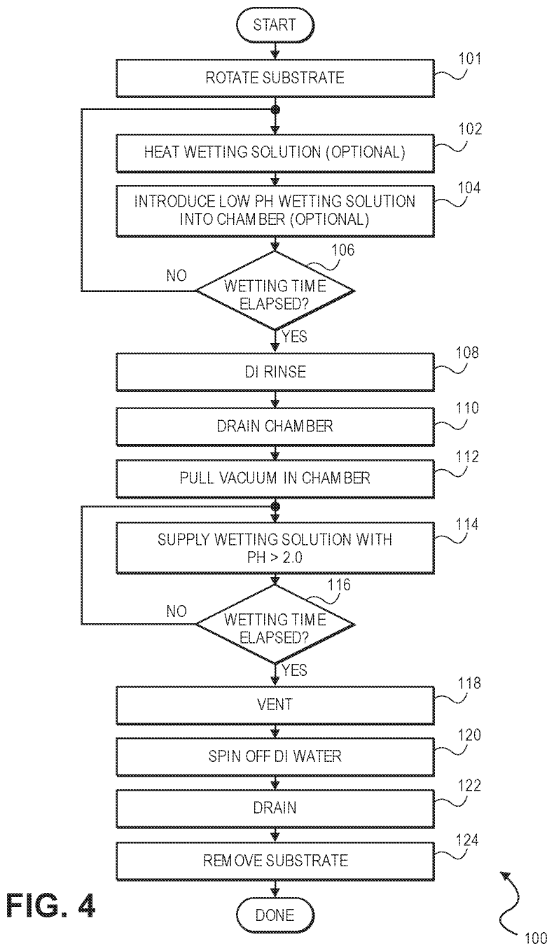

Referring to FIG. 4, a flow diagram 100 illustrating a second chemical and/or heated wetting process performed by tool 10 on a substrate 16 is shown. Again, the steps outlined below are coordinated by the system controller 48. Again, it should be noted that the various parameters and values, such as pressure ranges, rpm rates, temperature ranges, flow rates, etc., provided below are exemplary and are not intended to be construed as limiting. Other parameters and values may be used.

In step 101, the system controller 48 directs the mechanism 18 to rotate a substrate 16 on substrate holder 14.

In optional step 102, the system controller 48 directs the heater 26 to heat wetting solution from tank 22. In various embodiments, the wetting solution is heated to a temperature range of 20 to 50° C. In a specific embodiment, the temperature is 40° C.

In optional step 104, the system controller 48 opens the valve 30, allowing a wetting solution having a pH of 2.0 or less to be sprayed into the chamber by nozzle(s) 32.

Note, with this particular embodiment, the wetting solution sprayed onto the substrate without pulling a vacuum in the chamber 12.

In decision 106, the system controller 48 monitors the amount of time the substrate is exposed to the wetting solution having a pH of 2.0 or less and/or heated to a temperature range of 20 to 50° C. If a predetermined period of time is not exceeded, steps 102 and/or 104 are continually performed. In various embodiments, the predetermined period of time may range from 10 to 120 seconds.

In step 108, after the predetermined period of time has elapsed, the system controller 48 directs valve 30 to direct DI water into the chamber. As a result, the spinning substrate 16 is rinsed with DI water sprayed from nozzle 32. In various embodiments, the DI water rinse may range from 10 to 120 seconds.

In step 110, the system controller 48 opens the valve 44, allowing the wetting solution and the DI water to drain out of the chamber. In optional steps (not illustrated) the drained wetting solution and/or DI water may be recycled by station 46.

In step 112, the system controller 48 closes the chamber and opens valve 36. As a result, a vacuum pressure is created in the chamber 12 by the vacuum pump 34. In various embodiments, the vacuum pressure may range from 70 to 100 Torr.

In step 114, the system controller 48 opens the valve 30, allowing a wetting solution having a pH of more than 2.0 to be sprayed into the chamber 12 by nozzle(s) 32.

In decision 116, the system controller 48 monitors the amount of time the substrate is exposed to the wetting solution having a pH level of more than 2.0. If a predetermined period of time is not exceeded, steps 114 is continually performed. In various embodiments, the predetermined period of time may range from 30 to 120 seconds.

In step 118, after the predetermined period of time has expired, the system controller 48 opens a valve 40, allowing the chamber 12 to vent with a gas from supply 38.

In step 120, the DI water is sprayed into the chamber 12, rinsing the spinning substrate.

In step 122, the system controller 48 opens valve 42 allowing the wetting solution and DI water to drain. Again, the drained wetting solution may optionally be recycled at the recycling station 46.

Finally, in step 124, the wetted substrate is removed from the chamber 12. Thereafter, the substrate can be moved to a plating chamber for plating.

The above process has the advantage of making the resist more hydrophilic while reducing the possibility of harming the walls of the features 54. This particular wetting sequence is therefore advantageous having substrate features that are very small (e.g., line widths that are approximately 2.0 microns or less and have a pitch of 2.0 microns or less).

It should be noted that the above embodiments are merely exemplary and are intended to show possible sequences with wetting solutions having a pH of 2.0 or less and/or heated in the range of 20 to 50° C. In no way, however, should these specific process flows be construed as limiting. On the contrary, any process flow with wetting solutions having a pH of 2.0 or less and/or heated in the range of 20 to 50° C. can also be integrated with additional wetting steps with solutions having a pH of more than 2.0, at ambient or room temperatures, with DI water, etc. For example:

In another alternative embodiment, the substrate wetting tool 10 may maintain the chamber 12 at a vacuum pressure, wet the substrate with the wetting solution having a pH level of 2.0 or less and/or heated in the range of 20 to 50° C. while the substrate is supported and rotated by the substrate pedestal, vent the chamber and stop wetting the substrate with the wetting solution after a first predetermined period of time, drain the wetting solution from the chamber, wet the substrate with a second wetting solution for a second time while the substrate is supported and rotated by the substrate pedestal and the chamber is vented. With this embodiment, wetting solution and the second wetting solution can be either the same or different, can have a pH level that is 2.0 or less or more than 2.0, and/or may have an elevated temperature in the range of 20 to 50° C. or can be at ambient or room temperature.

In yet another alternative embodiment, the substrate wetting tool 10 may maintain the chamber 12 at a vacuum pressure, wet the substrate with the wetting solution having a pH level of 2.0 or less and/or heated in the range of 20 to 50° C. while the substrate is supported and rotated by the substrate pedestal, vent the chamber and stop wetting the substrate with the wetting solution after a predetermined period of time, rinse the substrate with DI water after venting the chamber and the stopping of the wetting of the substrate with the wetting solution, maintain the chamber at the vacuum pressure a second time and wet the substrate a second time with a second wetting solution while the substrate is supported and rotated by the substrate pedestal, the second wetting solution having a pH level greater than 2.0.

Also, the time period a substrate is exposed to a wetting solution and/or DI water, rpm rate, vacuum pressure, venting pressure, etc. are all factors that may be widely varied from process flow to process flow and should not be construed as limiting by the values provided herein.

In yet other embodiments, the tool 10 including the wetting chamber 12 may be implemented in a wide variety of different types of tools. For instance, the tool may be a stand-alone wetting tool with one or multiple wetting chambers 12. Alternatively, the tool may be some type of hybrid tool that includes one or more wetting chamber(s) 12 along with other capabilities, such as one or more electroplating chamber(s).

In addition, although semiconductor wafer substrates are mentioned herein, it should be understood that the wetting tool as described herein may be used with any type of substrate.

Although only a few embodiments have been described in detail, it should be appreciated that the present application may be implemented in many other forms without departing from the spirit or scope of the disclosure provided herein. For instance, the substrate can be a semiconductor wafer, a discrete semiconductor device, a flat panel display, or any other type of work piece.

Therefore, the present embodiments should be considered illustrative and not restrictive and is not to be limited to the details given herein, but may be modified within the scope and equivalents of the appended claims.

What is claimed is:

1. A substrate wetting tool, comprising
a chamber;
a substrate pedestal for supporting a substrate within the chamber;
a wetting solution distribution system for introducing a wetting solution into the chamber, the wetting solution having a pH of 2.0 or less and a temperature ranging from 20 to 50° C.

2. The substrate wetting tool of claim 1, further comprising a heater for heating the wetting solution to the temperature ranging from 20 to 50° C.

3. The substrate wetting tool of claim 1, further comprising a pH control system for maintaining the pH of the wetting solution at 2.0 or less.

4. The substrate wetting tool of claim 1, further comprising a recycle station for recycling the wetting solution drained from the chamber.

5. The substrate wetting tool of claim 1, further comprising a vacuum pump for creating a vacuum in the processing chamber.

6. The substrate wetting tool of claim 1, further comprising a vent for venting the chamber.

7. The substrate wetting tool of claim 1, further comprising a drain for draining the wetting solution from the chamber.

8. The substrate wetting tool of claim 1, further comprising a mechanism to rotate the substrate pedestal supporting the substrate.

9. The substrate wetting tool of claim 1, wherein the wetting solution distribution system further includes a storage tank for storing the wetting solution and one or more spray nozzles for spraying the wetting solution inside the chamber.

10. The substrate tool of claim 1, wherein the wetting solution is one of the following (a) an inorganic acid, (b) an organic acid, (c) a dissolved gas in water, (d) dissolved carbon dioxide in water, (e) DI water, (f) DI and degassed water, (g) carbonic acid, (h) sulfuric acid, and (i) methane sulfonic acid.

11. The substrate wetting tool of claim 1, further configured to:
maintain the chamber at a vacuum pressure;
wet the substrate with the wetting solution while the substrate is supported and rotated by the substrate pedestal;
vent the chamber and stop wetting the substrate with the wetting solution after a predetermined period of time; and
rinse the substrate with deionized (DI) water after venting the chamber and the stopping of the wetting of the substrate with the wetting solution.

12. The substrate wetting tool of claim 1, further configured to:
maintain the chamber at a vacuum pressure;
wet the substrate with the wetting solution while the substrate is supported and rotated by the substrate pedestal;
vent the chamber and stop wetting the substrate with the wetting solution after a first predetermined period of time;
drain the wetting solution from the chamber; and
wet the substrate with a second wetting solution for a second time while the substrate is supported and rotated by the substrate pedestal and the chamber is vented wherein the wetting solution and the second wetting solution can be either the same or different.

13. The substrate wetting tool of claim 1, further configured to:
maintain the chamber at a vacuum pressure;
wet the substrate with the wetting solution while the substrate is supported and rotated by the substrate pedestal;
vent the chamber and stop wetting the substrate with the wetting solution after a predetermined period of time;
rinse the substrate with deionized (DI) water after venting the chamber and the stopping of the wetting of the substrate with the wetting solution;
maintain the chamber at the vacuum pressure a second time; and
wet the substrate a second time with a second wetting solution while the substrate is supported and rotated by the substrate pedestal, the second wetting solution having a pH greater than 2.0.

14. A substrate wetting tool, comprising
a chamber;
a substrate pedestal for supporting a substrate within the chamber;
a wetting solution distribution system for introducing a wetting solution into the chamber, the wetting solution having a pH of 2.0 or less.

15. The substrate wetting tool of claim 14, further comprising a heater for heating the wetting solution to the temperature ranging from 20 to 50° C.

16. The substrate wetting tool of claim 14, further comprising a pH control system for maintaining the pH of the wetting solution at 2.0 or less.

17. The substrate wetting tool of claim 1, further comprising a recycle station for recycling the wetting solution drained from the chamber.

18. The substrate wetting tool of claim 14, wherein the wetting solution is one of the following (a) an inorganic acid, (b) an organic acid, (c) a dissolved gas in water, (d) dissolved carbon dioxide in water, (e) DI water, (f) DI and degassed water, (g) carbonic acid, (h) sulfuric acid, and (i) methane sulfonic acid.

19. A substrate wetting tool, comprising
a chamber;
a substrate pedestal for supporting a substrate within the chamber;
a wetting solution distribution system for introducing a wetting solution into the chamber, the wetting solution having a temperature ranging from 20 to 50° C.

20. The substrate wetting tool of claim 19, further comprising a heater for heating the wetting solution to the temperature ranging from 20 to 50° C.

21. The substrate wetting tool of claim 19, wherein the wetting solution has a pH of 2.0 or less.

22. The substrate wetting tool of claim 19, wherein the wetting solution is one of the following (a) an inorganic acid, (b) an organic acid, (c) a dissolved gas in water, (d) dissolved carbon dioxide in water, (e) DI water, (f) DI and degassed water, (g) carbonic acid, (h) sulfuric acid, and (i) methane sulfonic acid.

23. A substrate wetting tool comprising a wetting solution distribution system arranged to wet a substrate in a chamber, the wetting solution having a pH of 2.0 or less and a temperature ranging from 20 to 50° C.

24. The substrate wetting tool of claim 23, further comprising a vacuum pump for creating a vacuum pressure in the chamber when the wetting solution is wetting the substrate.

25. The substrate wetting tool of claim 24, wherein the vacuum pressure ranges from 25 to 100 Torr.

26. The substrate wetting tool of claim 23, further comprising a pedestal support for supporting and rotating the substrate when wetted by the wetting solution.

27. The substrate wetting tool of claim 26, wherein the pedestal support rotates the substrate at a rate of one of the following:
(a) ranging from 80 to 200 revolutions per minute (rpm);
(b) 40 to 300 rpm;
(d) 20 to 400 rmp;
(e) more than 400 rmps;
(f) less than 20 rmps.

28. The substrate tool of claim 23, further comprising a vent for venting the chamber after the substrate has been wetted by the wetting solution for a predetermined period of time.

29. The substrate tool of claim 28, comprising a pedestal support for supporting and rotating the substrate after venting the chamber, the spinning of the substrate after the venting of the chamber resulting in the wetting solution spinning off the substrate.

30. The substrate tool of claim 28, wherein the wetting solution distribution system is further arranged to wet the substrate a second time with deionized water.

31. The substrate tool of claim 30, wherein the wetting solution distribution system is further arranged to wet the substrate a third time with a second wetting solution having a pH greater than 2.0.

32. The substrate tool of claim 31, wherein the second wetting solution is at ambient temperature.

33. The substrate tool of claim 28, wherein the wetting solution distribution system is further arranged to wet the substrate a second time with a second wetting solution, wherein the wetting solution and the second wetting solution are either the same or different.

34. The substrate tool of claim 23, wherein the wetting solution is one of the following (a) an inorganic acid, (b) an organic acid, (c) a dissolved gas in water, (d) dissolved carbon dioxide in water, (e) DI water, (f) DI and degassed water, (g) carbonic acid, (h) sulfuric acid, and (i) methane sulfonic acid.
